(19) United States
(12) Patent Application Publication
(10) Pub. No.: US 2025/0344375 A1
(43) Pub. Date: Nov. 6, 2025

(54) BLOCK SEPARATION FOR DATA LINE CUT IN THREE-DIMENSIONAL MEMORY DEVICE

(71) Applicant: Micron Technology, inc., Boise, ID (US)

(72) Inventors: Nicolo' Gravellini, Milano, MI (US); Giovanni Mazzone, Villasanta, MI (US); Anna Maria Conti, Milano, MI (US); Lorenzo Pedrazzetti, Soncino (IT); Paolo Tessariol, Arcore (IT)

(21) Appl. No.: 19/188,657

(22) Filed: Apr. 24, 2025

Related U.S. Application Data
(60) Provisional application No. 63/643,205, filed on May 6, 2024.

(51) Int. Cl. H10B 12/00

(52) U.S. Cl. CPC H10B 12/482; H10B 12/02

(57) ABSTRACT

A variety of applications can include one or more memory devices comprising an array of pillars of memory cells, where the memory cells are stacked in a vertical direction within the pillars and the array of pillars are organized in blocks. Separation regions between blocks can be defined by spacing of a single row of pillars, except for a number of dedicated separation regions providing spacing defined by three rows of pillars.

### PRIORITY APPLICATION

This application claims the benefit of priority to U.S. Provisional Application Ser. No. 63/643,205, filed May 6, 2024, which is incorporated herein by reference in its entirety.

### FIELD OF THE DISCLOSURE

Embodiments of the disclosure relate generally to integrated circuits, and more specifically, to memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered and includes flash memory, read-only memory (ROM), electrically erasable programmable ROM (EEPROM), erasable programmable ROM (EPROM), resistance-variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices such as, but not limited to, 3D memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates an example portion of a block architecture of an array of blocks in a three-dimensional memory device during formation, in which connected BLs are to be cut to form independent BLs, in accordance with various embodiments.

FIG. 2 illustrates an example half-data line scenario in an arrangement of blocks of pillars with a shrunken pillar pitch across a slit for a cut to form the half-data lines, in accordance with various embodiments.

FIG. 3 shows an example portion of a block architecture of an array of blocks in a three-dimensional memory device during formation, where connected BLs are to be cut to form independent BLs, in accordance with various embodiments.

FIG. 4 illustrates the portion of FIG. 3 after data lines have been cut based on a selected location in the portion, in accordance with various embodiments.

FIG. 5 illustrates a structure for a packet of connected BLs formed in fabrication of a three-dimensional memory device to couple to memory cells in selected active pillars, in accordance with various embodiments.

FIG. 6 illustrates a top view of an example structure in a plane in the x-y direction, generated in a process flow of forming data lines for a memory array after formation of pillars of memory cells of the memory array, in accordance with various embodiments.

FIG. 7 shows an example structure after further processing of the structure of FIG. 6, in accordance with various embodiments.

FIG. 8 shows an example structure after further processing of the structure of FIG. 7, in accordance with various embodiments.

FIG. 9 is a flow diagram of features of an example method of forming components of a memory device, in accordance with various embodiments.

FIG. 10 a flow diagram of features of an example method of forming components of a memory device, in accordance with various embodiments.

FIG. 11 is a schematic of an example, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

As the array density for a 3D memory device increases across generations of memory devices, the number of tiers of memory cells of such memory device increases as well, resulting in a remarkable decrease of the string current. Decrease of string current unavoidably worsens the sensing operations. The array can be organized into blocks of pillars containing the tiers of memory cells. One current architectural approach to address this issue, which aims at partially mitigating this issue, is a half-data line (half-BL) arrangement. Half-BL is segmentation of the BLs for the array in a plane of two different branches, halving the capacitive load of each BL. However, the implementation of such an architectural element could appreciably degrade the array efficiency (AE), whenever the region that provides block separation is not large enough to accommodate the BL cut for the half-BL arrangement such that dummy blocks are introduced into the array of blocks. A dummy block is a block of pillars structured in a manner similar to the pillars containing memory cells stacked vertically within the pillars that are structured for assignment for data storage or as spares for data storage, except that the dummy block is not provided with structure to operate as a data storage structure. The inactivity of a dummy block can be realized by not forming memory cells in the pillars of the dummy block or without making the electrical coupling to the pillars of the dummy pillars. An active block is a block of pillars containing memory cells that have electrical coupling to function as a memory cells after completion of the fabrication of the memory device. Blocks structured as spare blocks of memory cell are active blocks that have not been activated for use in data storage.

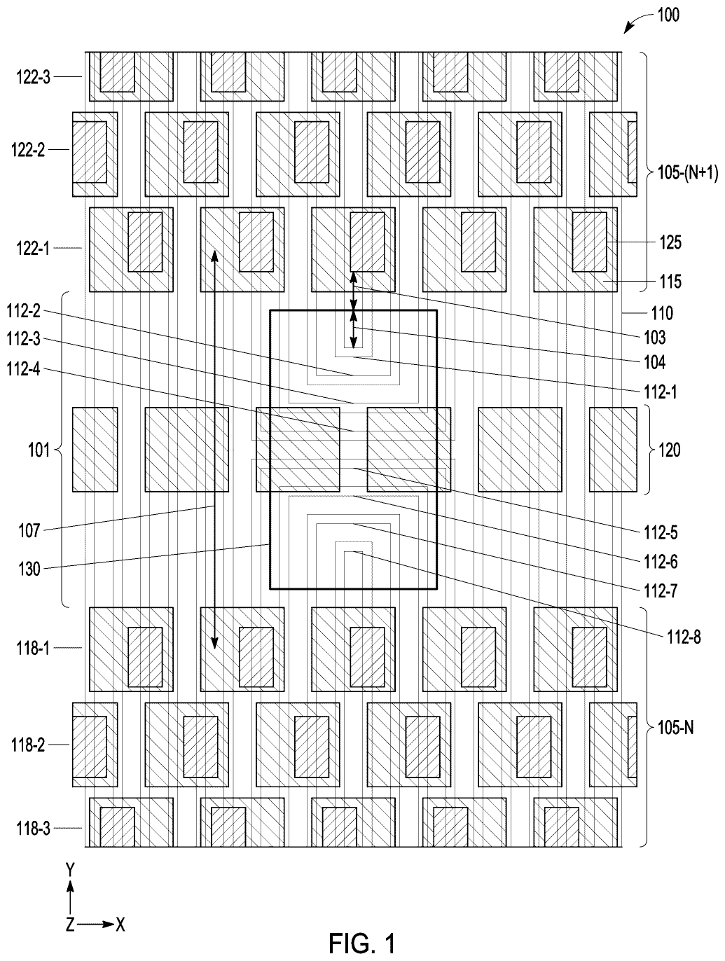

FIG. 1 illustrates an example portion 100 of a block architecture of an array of blocks in a 3D memory device during formation, in which connected BLs are to be cut to form independent BLs. Each block has rows of pillars in which memory cells are stacked. A row of pillars can be referred to as a pillar row. Each level of memory cells can form a tier of memory cells of the memory device. The pillars of a block running along the x-direction shown in FIG. 1 are substantially parallel to each other. The block architecture can include multiple blocks, where directly adjacent blocks are separated by a distance equal to or less than a single row of pillars in the y-direction, except along regions including selected locations at which BL are to be cut. At these regions, perpendicular to the running of BLs, directly adjacent blocks after separated by a distance equal to a single row of pillars plus additional space on both sides of the single row to facilitate the BL cut at the selected locations. Two blocks are directly adjacent each other in a plane when there is no intervening block between the two blocks in the plane.

Portion 100 includes a block 105-N and a block 105-(N+1), where block 105-N and block 105-(N+1) include at least rows 122-1 . . . 122-3 of pillars and at least rows 118-1 . . . 118-3 of pillars, respectively. Each pillar 115 of memory cells in these rows can be coupled to a BL 110 by a BL contact 125. Each pillar 115 is shown having a rectangular shape in the plane perpendicular to the vertical dimension of pillar 115. Other cross-sectional shapes in the plane can be used, for example, substantially circular shapes. For ease of presentation, reference labels 115, 125, and 110 are shown for one instance of a pillar coupled to a BL using a BL contact. Though three rows are shown in each of blocks 105-N and 105-(N+1), the blocks of the memory device can include more or fewer than three blocks of rows of pillars.

Portion 100 includes a block separation region 101 at which a BL cut can be placed during fabrication of the memory device. Block separation region 101 is a slit between two directly adjacent blocks 105-N and 105-(N+1). Block separation region 101 can include a row 120 of pillars perpendicular to the running of BLs 110, where block separation region 101 separates block 105-N from directly adjacent block 105-(N+1) by a distance equal to a single row of pillars plus additional space on both sides of the single row to facilitate the BL cut at a selected location 130. Block separations where BL cuts are not executed can be composed by a single row of pillar plus an additional space. What differs from block separations where BLs are cut versus block separations where BLs are not cut is that in the cut case the additional space should be larger. The lack of such larger additional space may lead to other actions taken with respect to the BL cuts, such as introducing dummy blocks into the array of blocks. Row 120 can be merged, forming a one pillar row merged pillar slit (M PS). Selected location 130 can be realized by a mask to facilitate the cutting of connected BLs at two opposite edges of the mask across BLs to form individual, electrically separate BLs. In formation of BLs 110, the BLs can be formed as a set of connected data lines depending on the process for forming the BLs. Selected location 130, which can be a mask, can be formed on a set of connected BLs, where the set of connected BLs are connected in a pair-wise manner by BL connectors 112-1 . . . 112-8. In this example, cutting of BLs at two opposite edges of the mask across connected BLs forms two separate sets of BLs, which can be referred to as half-BLs. BLs 110 on the sides of selected location 130 are arranged as sets of connected BLs at other locations along the x-direction and at locations in the x-direction separated from selected location 130 along the y-direction, but not shown in FIG. 1.

In portion 100 of the block architecture, a pillar pitch 107 across the slit defined by block separation region 101 may be sufficiently large to make possible this placing of the BL cut at selected location 130 in block separation region 101. Pillar pitch is the distance from a center of one pillar in one row to a directly adjacent pillar in a directly adjacent row. Pillar pitch across the slit is the distance from a center of one pillar on a first side of the slit to a pillar on a second side of the slit directly opposite the first side. The sufficiency of the size of the slit can be determined. in part, by a margin 104 of the selected location 130 to BL connector 112-1 as being equal to the distance between the edge of selected location 130 and the edge of the first BL coupling, which is BL connector 112-1 in example portion 100. The sufficiency of the size of the slit can be determined. in part, by a margin 103 of the selected location 130 to BL contact 125 as being equal to the distance between the edge of selected location 130 and BL contact 125 of the first pillar in the y-direction from BL connector 112-1 for the connected BLs. With selected location 130 being symmetric to row 120, the two margins can be the same from each edge of selected location 130 that is perpendicular to the running of the BLs. However, margins 103 and 104 may not be sufficient, which would lead to BL cuts being made in adjacent blocks 105-N and 105-(N+1), which would make adjacent blocks 105-N and 105-(N+1) dummy blocks that are inactive for data storage.

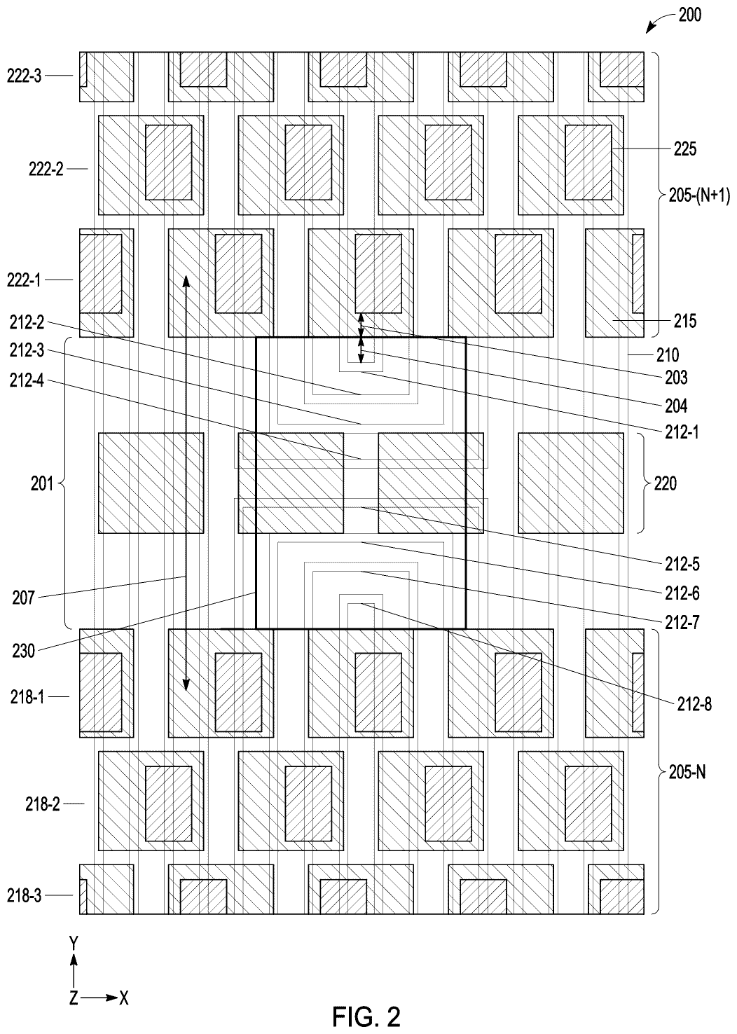

FIG. 2 illustrates a half-BL scenario in an arrangement of blocks of pillars with a shrunken pillar pitch 207 across a slit for a cut to form half-BLs. FIG. 2 shows a portion 200 of a block architecture of an array of blocks in a 3D memory device during formation, where connected BLs are to be cut to form independent B Ls. Each block has rows of pillars in which memory cells are stacked. Each level of memory cells can form a tier of memory cells of the memory device. The pillars of a block running along the x-direction shown in FIG. 2 are substantially parallel to each other. The block architecture can include multiple blocks, where directly adjacent blocks are separated by a distance equal to or less than a single row of pillars in the y-direction, except along regions including selected locations at which BL are to be cut. At these regions, perpendicular to the running of BLs, directly adjacent blocks after separated by a distance equal to a single row of pillars. A difference between portion 200 and portion 100 of FIG. 1 is that portion 200 does not include additional space on both sides of single row separation of pillar row 220 with respect to connected BL lines to facilitate the BL cut at the selected locations, which provides the shrunken pillar pitch 207.

Portion 200 includes a block 205-N and a block 205-(N+1), where block 205-N and block 205-(N+1) include at least rows 222-1 . . . 222-3 of pillars and at least rows 218-2 . . . 218-3 of pillars, respectively. Each pillar 215 of memory cells in these rows can be coupled to a BL 210 by a BL contact 225. Each pillar 215 is shown having a rectangular shape in the plane perpendicular to the vertical dimension of pillar 215. Other cross-sectional shapes in the plane can be used, for example, substantially circular shapes. For ease of presentation reference, labels 215, 225, and 210 are shown for one instance of a pillar coupled to a BL using a BL contact. Though three rows are shown in each of blocks 205-N and 205-(N+1), the blocks of the memory device can include more or fewer than three blocks of rows of pillars.

Portion 200 includes a block separation region 201 at which a BL cut can be placed during fabrication of the memory device. Block separation region 201 is a slit between two directly adjacent blocks 205-N and 205-(N+1). Block separation region 201 includes a row 220 of pillars perpendicular to the running of BLs 210, where block separation region 201 separates block 205-N from directly adjacent block 205-(N+1). Row 220 can be merged, forming a one pillar row merged pillar slit (MPS). Selected location 230 can be realized by a mask to facilitate the cutting of connected BLs at two opposite edges of the mask across BLs to form individual, electrically separate BLs. In formation of BLs 210, the BLs can be formed as a set of connected BLs depending on the process for forming the BLs. Selected location 230, which can be a mask, is formed on a set of connected BLs, where the set of connected BLs are connected in a pair-wise manner by BL connectors 212-1 . . . 212-8. In this example, cutting of BLs at two opposite edges of the mask across connected BLs forms two separate sets of BLs, forming half-BLs. BLs 210 on the sides of selected location 230 are arranged as sets of connected BLs at other locations along the x-direction and at locations in the x-direction separated from selection location 230 along the y-direction, but not shown in FIG. 2.

In portion 200 of the block architecture, the sufficiency of the size of block separation region 201 can be determined. in part, by the margin 204 of the selected location 230 to BL connector 212-1 as being equal to the distance between the edge of selected location 230 and the edge of the first BL coupling, BL connector 212-1. The sufficiency of the size of the slit can be determined. in part, by the margin 203 of the selected location 230 to BL contact 225 as being equal to the distance between the edge of selected location 230 and BL contact 225 of the first pillar in the y-direction from BL connector 212-1 for the connected BLs. With selection location 230 symmetric to row 220, the two margins can be the same from each edge of selected location 230 that is perpendicular to the running of the BLs. Portion 200 of FIG. 2 shows an instance in which margins 203 and 204 tend to be insufficient. As pillar pitch 207 across the slit, block separation region 201, is reduced, there is an increase of the failure rate for both margins 203 and 204. There is not enough space to place the BL cut at selected location 230 of block separation region 201, such that a dummy block is introduced to mitigate occurrence of an unacceptable failure rate. However, with the introduction of one or more dummy blocks, there is an AE loss.

In various embodiments, a block separation region that corresponds to BL cut locations can be generated using three rows of pillars, while separation regions that are not allocated to BL cuts can be generated using a single row of pillars. The three row of pillars become a three row MPS with the single row of pillars become a one row MPS. The implementation of three row MPS only for the regions of block separation that correspond to BL cut locations, maintaining the one row MPS for other block separation regions, provides a configuration that avoids A E degradation, as the introduction of dummy blocks can be avoided. In addition, this implementation does not present additional tier bending issues and does not degrade a replacement gate (RG) process.

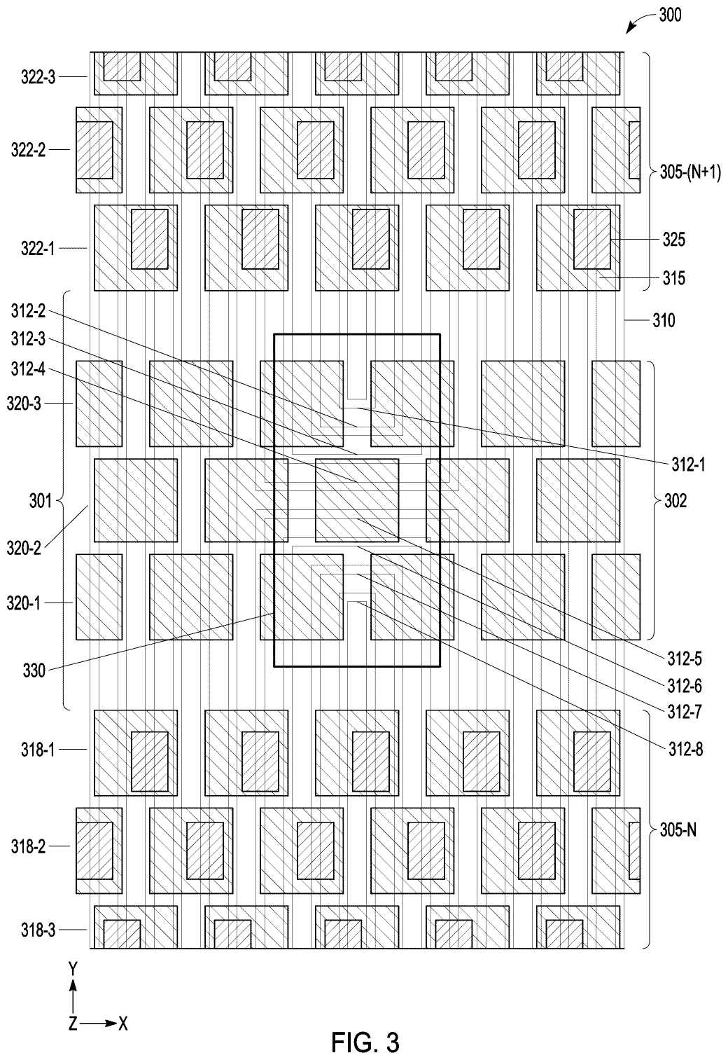

FIG. 3 shows a portion 300 of a block architecture of an array of blocks in a 3D memory device during formation, where connected BLs are to be cut to form independent BLs. Each block has rows of pillars in which memory cells are stacked. FIG. 3 illustrates an arrangement from selectively enlarging only the block separation regions where the BL cut is to be executed, keeping the other block separation regions unchanged. The separation slit can be slit enlarged by modifying a one pillar row MPS into a three pillar rows MPS. This arrangement aims at ensuring the half-BL implementation in the case of shrunk block pitch or shrunk pillar pitch across slit, without using dummy blocks, without A E degradation. The pillar pitch across slit enlarging being performed by adding two MPS rows keeps the rail width unaltered for all blocks, without therefore causing any tier collapse issues in the BL cut regions. Rail width is the distance between the MPS row and the first pillar row of an adjacent active block.

FIG. 3 shows a portion 300 of a block architecture of an array of blocks in a 3D memory device during formation, with each block having rows of pillars in which memory cells are stacked, where connected BLs are to be cut to form independent BLs. Each level of memory cells can form a tier of memory cells of the memory device. The pillars of a block running along the x-direction shown in FIG. 3 are substantially parallel to each other. The block architecture can include multiple blocks, where directly adjacent blocks are separated by a distance equal to or less than a single row of pillars in the x-direction, except along separation regions including selected locations at which BL are to be cut. At these separation regions, perpendicular to the running of BLs, directly adjacent blocks are separated by a distance equal to three rows of pillars and additional space on both sides of the triple-row separation to facilitate the BL cut at selected locations in the separation regions.

Portion 300 includes a block 305-N and a block 305-(N+1), where block 305-N and block 305-(N+1) include at least rows 322-1 . . . 322-3 of pillars and at least rows 318-2 . . . 318-3 of pillars, respectively. Each pillar 315 of memory cells in these rows can be coupled to a BL 310 by a BL contact 325. Each pillar 315 is shown having a rectangular shape in the plane perpendicular to the vertical dimension of pillar 315. Other cross-sectional shapes in the plane can be used, for example, substantially circular shapes. For ease of presentation reference, labels 315, 325, and 310 are shown for one instance of a pillar coupled to a BL using a BL contact. Though three rows are shown in each of blocks 305-N and 305-(N+1), the blocks of the memory device can include more or fewer than three blocks of rows of pillars.

Portion 300 includes a block separation region 302 at which a BL cut can be placed during fabrication of the memory device. Block separation region 302 is a slit between two directly adjacent blocks 305-N and 305-(N+1). Block separation region 302 includes row 320-1 of pillars, row 320-2 of pillars, and row 320-3 of pillars perpendicular to the running of BLs 310, where block separation region 302 separates block 305-N from directly adjacent block 305-(N+1). Rows 320-1, 320-2, and 320-3 of pillars can be merged, forming a three pillar row merged pillar slit (MPS). Selected location 330 can be realized by a mask to facilitate the cutting of connected BLs at two opposite edges of the mask across BLs to form individual, electrically separate BLs. In formation of BLs 310, the BLs can be formed as a set of connected BLs depending on the process for forming the BLs. Selected location 330, which can be a mask, is formed on a set of connected BLs, where the set of connected BLs are connected in a pair-wise manner by BL connectors 312-1 . . . 312-8. In this example, cutting of BLs at two opposite edges of the mask across connected BLs forms two separate sets of BLs, forming BLs. BLs 310 on the sides of selected location 330 are arranged as sets of connected BLs at other locations along the x-direction and at locations in the x-direction separated from selection location 330 along the y-direction, but not shown in FIG. 3.

Portion 300 provides a separation region providing more space for a BL cut procedure, without using dummy blocks. With the blocks of the array of blocks containing more than three rows of pillars, dummy blocks, formed with forming of the array, would reduce the amount of pillars for data storage.

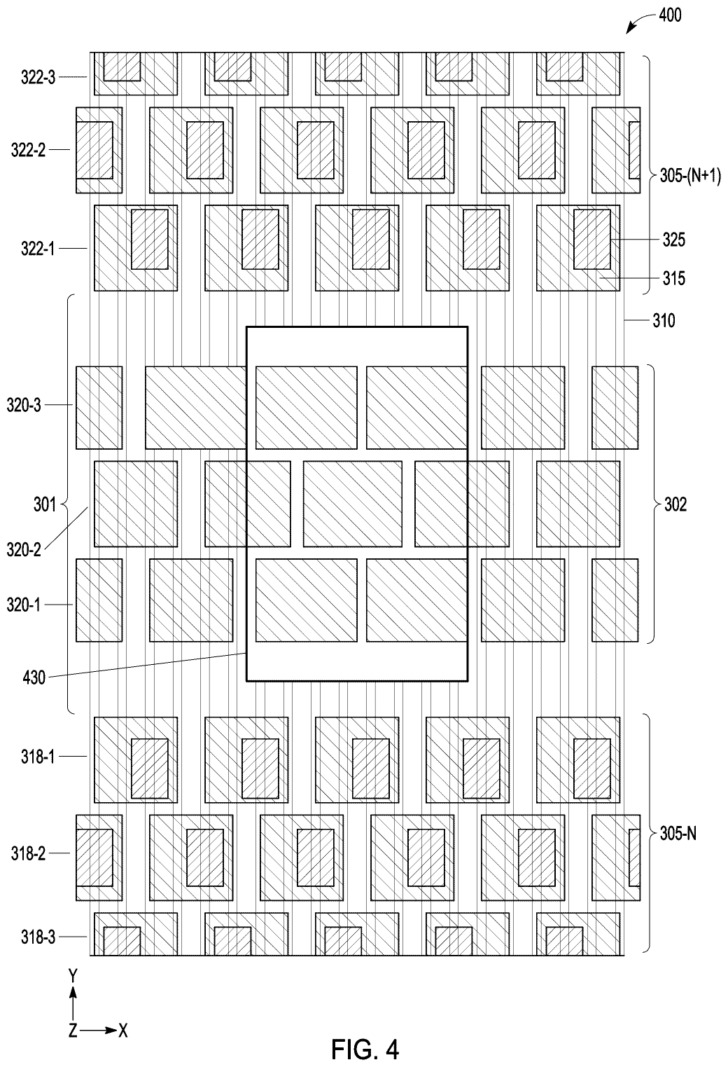

FIG. 4 illustrates portion 300 of FIG. 3 after BLs 310 have been cut based on selected location 330. The BLs have been cut at two opposite edges of selected location 330 across BLs 310 to form individual, electrically separate BLs from the connected BLs at selected location 330. The material for the connected BLs at selected location 330 have been removed such that BLs do not extend over region 430 corresponding to a mask used to cut the connected BLs.

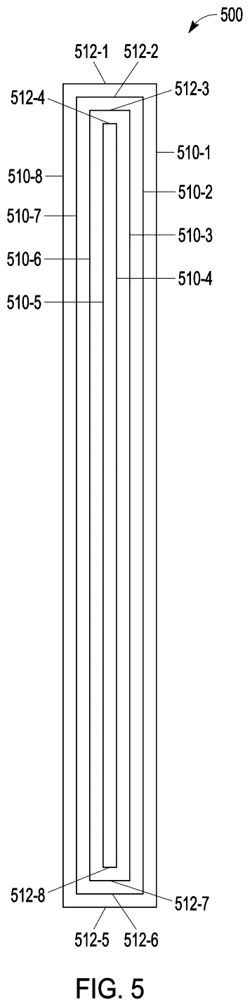

FIG. 5 illustrates a structure for a packet 500 of connected BLs formed in fabrication of a 3D memory device to couple to memory cells in selected active pillars. Packet 500 can include BLs 510-1 . . . 510-8 connected by BL connectors 512-1 . . . 512-8. BL connector 512-1 connects BL 510-1 to BL 510-8 at one end of packet 500 and BL connector 512-5 connects BL 510-1 to BL 510-8 at an opposite end of packet 500. BL connector 512-2 connects BL 510-2 to BL 510-7 at one end of packet 500 and BL connector 512-6 connects BL 510-2 to BL 510-7 at an opposite end of packet 500. BL connector 512-3 connects BL 510-3 to BL 510-6 at one end of packet 500 and BL connector 512-7 connects BL 510-3 to BL 510-6 at an opposite end of packet 500. BL connector 512-4 connects BL 510-4 to BL 510-5 at one end of packet 500 and BL connector 512-8 connects BL 510-4 to BL 510-5 at an opposite end of packet 500. The arrangement of eight BLs and four BL connectors of packet 500 is generated from a quad pitch process. Packets can be formed with a different number of BLs and BL connectors form a different pitch process. In the formation of a memory device as taught herein, when formed on an array of pillars of memory cells for a memory device, multiple packets can be formed on and above the pillars, with packets arranged in parallel, and multiple packets can be formed on and above the pillars with an end of one packet separated from an end of another packet. To form the independent BLs of a memory device, the ends of a packet, such as packet 500, are cut to remove the BL connectors.

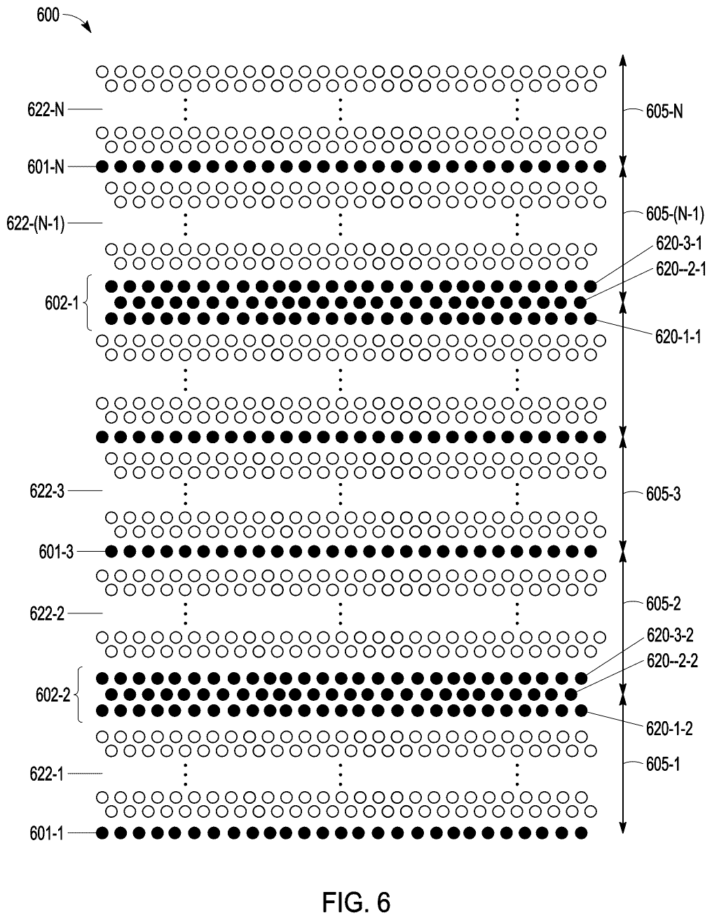

FIG. 6 illustrates top view of a structure 600 in a plane in the x-y direction, generated in a process flow of forming BLs for a memory array after formation of pillars of memory cells of the memory array. The memory cells stacked inside the pillars can have been formed before the process associated with forming the BLs, which can include forming BL contacts for the memory cells. An array of pillars has been formed organized in blocks of pillars with separation regions between directly adjacent composed of one single pillar row, except for two separation regions dedicated to BL cuts that have three pillar rows. Structure 600 includes blocks 605-1, 605-2, 605-3 . . . 605-N of pillars. Block 605-N can include rows 622-N of pillars and block 605-(N−1) can include rows 622-(N−1) of pillars, with single row 601-N separating block 605-N from block 605-(N−1). Block 605-3 can include rows 622-3 of pillars and block 605-2 can include rows 622-2 of pillars, with single row 601-3 separating block 605-3 from block 605-2. Block 605-1 can include rows 622-1 of pillars can include rows 622-1 of pillars with single row 601-1 separating block 605-1 from adjacent structures in the plane in the y-direction opposite block 605-N in the plane.

Structure 600 includes separation region 602-1 and separation region 602-2, which are parallel to each other and separated from each other by a number of blocks of pillars. Separation region 602-1 includes row 620-3-1 of pillars, 620-2-1 of pillars, 620-1-1 of pillars and separation region 602-2 includes row 620-3-2 of pillars, 620-2-2 of pillars, 620-1-2 of pillars. Just the two separation regions 602-1 and 602-2, where BL cuts are to be executed at selected portions in these two separation regions, are enlarged from one row of pillars to three rows of pillars. All other separation regions remain the same, that is, a single row of pillars for separation.

The single pillar rows, such as single pillar rows 601-1, 601-3, and 601-N and three pillar rows of separation regions 602-1 and 602-2 are block separation pillars that electrically separate directly adjacent blocks of pillars that include memory cells. The block separation pillars are not active pillars for storing data. Pillars within blocks are active pillars that have memory cells for data storage. For instance, rows 622-N of pillars of block 605-N, rows 622-(N−1) of pillars of block 605-(N−1), rows 622-3 of pillars of block 605-3, rows 622-2 of pillars of block 605-2, and rows 622-1 of pillars of block 605-1 are active pillars. Though the pillars of FIG. 6 are shown with circular cross-sections in the plane, the pillars can have other cross-sectional shapes relative to the vertical direction such as, but not limited to, rectangles.

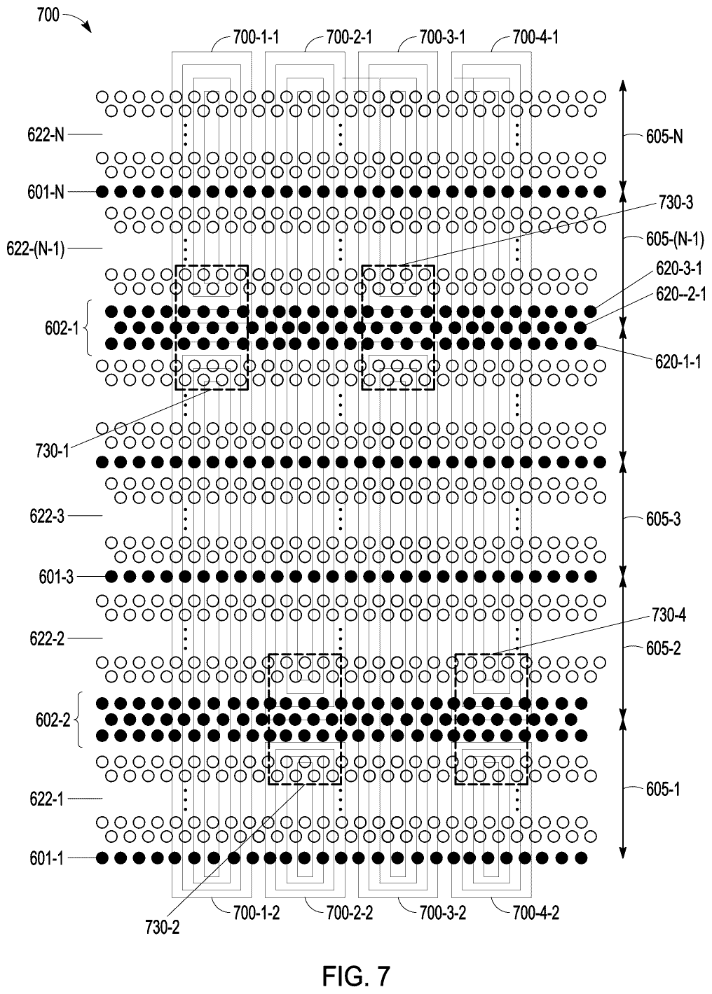

FIG. 7 shows a structure 700 after further processing of structure 600 of FIG. 6. Packets 700-1-1, 700-1-2, 700-2-1, 700-2-2, 700-3-1, 700-3-2, 700-4-1, and 700-4-2 of connected BLs have been formed in a plane extending across and on the blocks of structure 600, separation region 602-1, and separation region 602-2. These packets can be structured similar or identical to packet 500 of FIG. 5. Packets 700-1-1, 700-1-2, 700-2-1, 700-2-2, 700-3-1, 700-3-2, 700-4-1, and 700-4-2 of connected BLs are be formed on a plane above the array of pillars in a pairwise manner. Packets 700-1-1 and 700-1-2 have been formed colinear on the plane, where an end of packet 700-1-1 is separated from an end of packet 700-1-2 within separation region 602-1 by a distance that can be within the distance between row 620-3-1 of pillars and row 620-1-1 of pillars, for example by a distance equal to one of the three rows of pillars in separation region 602-1. Packets 700-2-1 and 700-2-2 have been formed colinear on the plane, where an end of packet 700-2-1 is separated from an end of packet 700-2-2 within separation region 602-2 by a distance that can be within the distance between row 620-3-2 of pillars and row 620-1-2 of pillars, for example by a distance equal to one of the three rows of pillars in separation region 602-2. Packets 700-3-1 and 700-3-2 have been formed colinear on the plane, where an end of packet 700-3-1 can be separated from an end of packet 700-3-2 within separation region 602-1 by a distance that is within the distance between row 620-3-1 of pillars and row 620-1-1 of pillars, for example by a distance equal to one of the three rows of pillars in separation region 602-1. Packets 700-4-1 and 700-4-2 have been formed colinear on the plane, where an end of packet 700-4-1 can be separated from an end of packet 700-4-2 within separation region 602-2 by a distance that is within the distance between row 620-3-2 of pillars and row 620-1-2 of pillars, for example by a distance equal to one of the three rows of pillars in separation region 602-2. Additional pairs of packets in a colinear arrangement can be formed to cover the complete array of pillars, where the ends of these pairs are alternating in separation regions 602-1 and 602-2.

Masks 730-1 and 730-3 have been formed at selected portions in separation region 602-1 and masks 730-2 and 730-4 have been formed at selected portions in separation region 602-2. Masks 730-1 and 730-3 can be colinear in the x-direction and masks 730-2 and 730-4 can be colinear in the x-direction. M ask 730-1 has been formed on ends of packets 700-1-1 and 700-1-2 in separation region 602-1. Mask 730-2 has been formed on ends of packets 700-2-1 and 700-2-2 in separation region 602-2. Mask 730-3 has been formed on ends of packets 700-3-1 and 700-3-2 in separation region 602-1. Mask 730-4 has been formed on ends of packets 700-4-1 and 700-4-2 in separation region 602-2. Additional masks can be formed to cover the complete array of pillars, where the masks are alternately in separation regions 602-1 and 602-2.

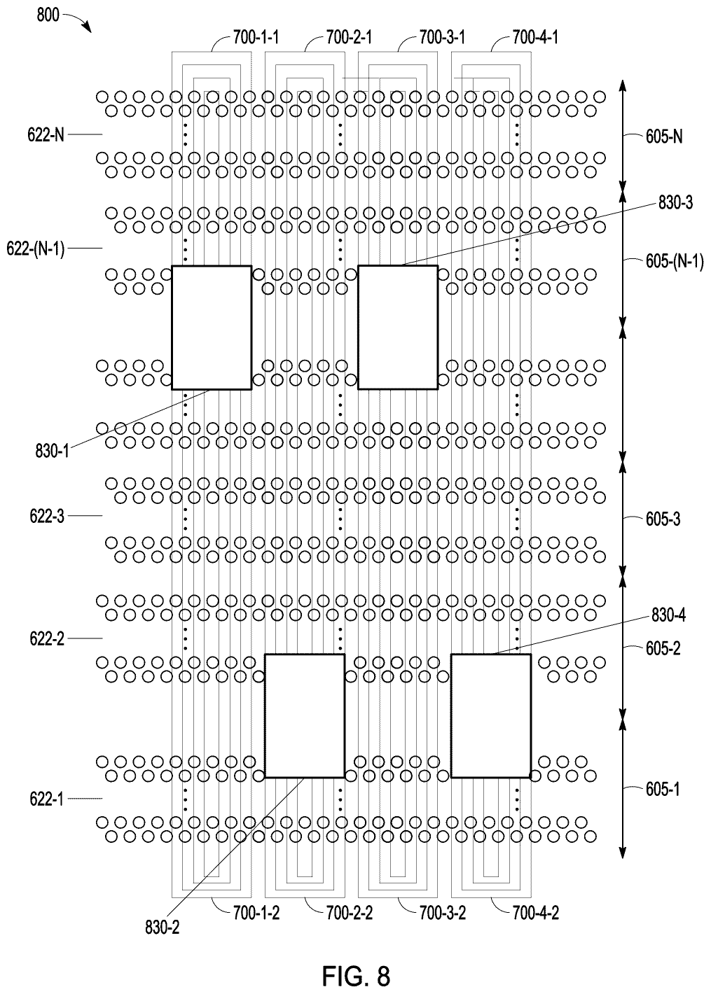

FIG. 8 shows a structure 800 after further processing of structure 700 of FIG. 7. For each of the colinear packet pairs 700-1-1 and 700-1-2, 700-2-1 and 700-2-2, 700-3-1 and 700-3-2, and 700-4-1 and 700-4-2, the packets of BL s have been cut at two opposite edges of the corresponding mask across the BLs, forming two sets of half bit lines in each of the colinear directions. Packet 700-1-1 and 700-1-2 have been cut at opposite edges of mask 730-1 along the direction of the rows of pillars perpendicular to the running of the BLs. Packet 700-2-1 and 700-2-2 have been cut at opposite edges of mask 730-2 along the direction of the rows of pillars perpendicular to the running of the BLs. Packet 700-3-1 and 700-3-2 have been cut at opposite edges of mask 730-3 along the direction of the rows of pillars perpendicular to the running of the BLs. Packet 700-4-1 and 700-4-2 have been cut at opposite edges of mask 730-4 along the direction of the rows of pillars perpendicular to the running of the BLs. The position of the cut of BLs has been alternated between the upper separation region (separation region 602-1) and the lower separation region (separation region 602-2). In conjunction with cutting BLs, the materials of the BLs over masks 730-1, 730-2, 730-3, and 730-4 have been removed, leaving regions 830-1, 830-2, 830-3, and 830-4 without BLs. Masks 730-1, 730-2, 730-3, and 730-4 can be optionally removed.

The pillars of the single row separation regions have been merged together, forming one pillar row MPSs. The pillars of the triple row separation regions have also been merged, forming three pillar row MPSs. These MPSs guarantee electrical separation between adjacent blocks. In a conventional BL arrangement, which is a non-half BL arrangement, the packets are cut at the two opposite ends of the array of blocks. In the half-BL configuration with two BL cuts in two separation regions, as discussed above, with cuts that are the center of the length of the BLs, the resulting BLs in the direction along the BLs are arranged in a symmetrical branches (50/50). The symmetrical branches formed by the cuts halves the capacitive load of each BL. When cuts provide colinear BLs split into two asymmetric branches, one BL having a length longer than the other. If, for example, BLs are cut into 70/30, instead of symmetrical 50/50, the BL capacitance reduces by 30% rather than 50%.

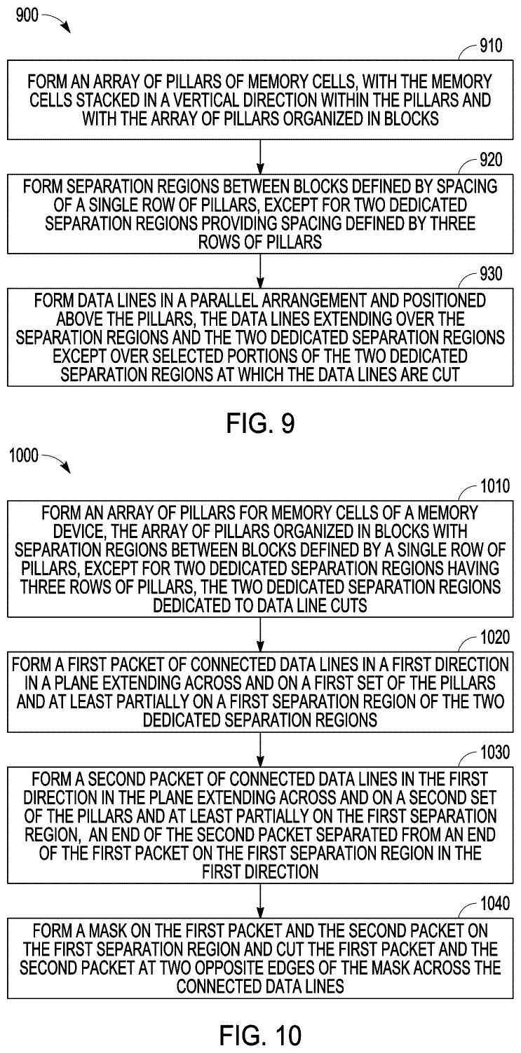

FIG. 9 is a flow diagram of features of an embodiment of an example method 900 of forming components of a memory device. At 910, an array of pillars of memory cells is formed, with the memory cells stacked in a vertical direction within the pillars and with the array of pillars organized in blocks. At 920, separation regions are formed between blocks defined by spacing of a single row of pillars, except for two dedicated separation regions providing spacing defined by three rows of pillars. At 930, BLs are formed in a parallel arrangement and positioned above the pillars, where each BL is coupled to memory cells of selected pillars. The BLs extend over the separation regions and the two dedicated separation regions except over selected portions of the two dedicated separation regions at which the BLs are cut forming two separate sets of BLs along a direction in a plane.

Variations of method 900 or methods similar to method 900 can include a number of different embodiments that may be combined depending on the application of such methods or the architecture or process flow of an integrated circuit for which such methods are implemented. Such methods can include forming the selected portions arranged in alternating positions between an upper portion of a plane in which the BLs are structured and a lower portion of the plane. Variations can include forming the selected portions having a width corresponding to width and separation of a packet of BLs structured in forming the BLs. Variations can include forming the BLs in packets of BLs having eight BLs arranged in parallel.

Variations of method 900 or methods similar to method 900 can include forming the array of pillars by organizing the array of pillars without forming dummy blocks that are not useable to store data. Variations can include forming memory cells within pillars of active blocks of the array before forming and cutting BLs in the selected portions of the two dedicated separation regions. Variations can include merging the three rows of pillars in each of the two separation regions and forming an electrical isolation between blocks directly adjacent the two separation regions.

FIG. 10 is a flow diagram of features of an embodiment of an example method 1000 of forming components of a memory device. At 1010, an array of pillars for memory cells of a memory device are formed, where the array of pillars are organized in blocks with separation regions between blocks defined by a single row of pillars, except for two dedicated separation regions having three rows of pillars. The two dedicated separation regions are dedicated to BL cuts. At 1020, a first packet of connected BLs are formed in a first direction in a plane extending across and on a first set of the pillars and at least partially on a first separation region of the two dedicated separation regions. At 1030, a second packet of connected BLs is formed in the first direction in the plane extending across and on a second set of the pillars and at least partially on the first separation region. An end of the second packet is separated from an end of the first packet on the first separation region in the first direction. At 1040, a mask is formed on the first packet and the second packet on the first separation region and the first packet and the second packet are cut at two opposite edges of the mask across the connected BLs. The process of method 100 or methods similar to method 1000 can be repeated for all other packets of connected BLs that are cut on the first and the second separation regions alternately.

Variations of method 1000 or methods similar to method 1000 can include a number of different embodiments that may be combined depending on the application of such methods or the architecture or process flow of an integrated circuit for which such methods are implemented. Such methods can include forming multiple pairs of packets in a manner similar to the above formation of the first packet and the second packet. The multiple pairs of packets can be constructed while forming the first packet and the second packet, with each pair in parallel with the other pairs of the multiple pairs of packets. Variations of method 1000 can include forming a third packet of connected BLs in a second direction in the plane extending across and on a third set of the pillars and at least partially on a second separation region of the two dedicated separation regions and forming a fourth packet of connected BLs with the fourth packet in the second direction in the plane extending across and on a fourth set of the pillars and at least partially on the second separation region. An end of the third packet can be separated from an end of the fourth packet on the second separation region in the second direction. A second mask can be formed on the third packet and the fourth packet on the second separation region. The third packet and the fourth packet can be cut at two opposite edges of the second mask across the connected BLs. The first direction and the second direction can be parallel to each other and the third packet and the fourth packet can be adjacent the first packet and the second packet without an intervening packet between combination of the third packet and the fourth packet and combination of the first packet and the second packet.

Variations of method 1000 or methods similar to method 1000 can include forming each packet of the first packet and the second packet by forming eight BLs in parallel to each other in the first direction and forming four BL connectors connecting the eight BLs on a pair-wise basis in a direction perpendicular to the first direction. Variations can include forming the mask on the four BL connectors.

Variations of method 1000 or methods similar to method 1000 can include forming the three rows in each of the two dedicated separation regions with the two dedicated separation regions separated from each other in the first direction by one or more active blocks of memory cells. Variations can include forming memory cells within pillars of active blocks of the array before forming and cutting the first packet and the second packet. Variations can include merging the three rows of pillars in each of the two separation regions and forming an electrical separation between blocks directly adjacent the two separation regions.

Various deposition techniques for components of structures in the process flows discussed above or similar structures and process flows can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Etching procedures can include, but are not limited to, wet etching, dry etching, and atomic layer etching deposition, among others.

In various embodiments, a memory device includes an array of pillars of memory cells, where the memory cells are stacked in a vertical direction within the pillars. The array of pillars can be organized in blocks. Separation regions between blocks can be defined by spacing of a single row of pillars, except for two dedicated separation regions providing spacing defined by three rows of pillars. BLs can be positioned in a parallel arrangement and positioned above the pillars, where each BL is coupled to memory cells of selected pillars. The BLs can extend over the separation regions and the two dedicated separation regions except over selected portions of the two dedicated separation regions at which the BLs are arranged in two separate sets.

Variations of such a memory device or similar memory device can include a number of different embodiments that may be combined depending on the application of such devices or the architecture or process flow of an integrated circuit in which such devices are implemented. Such memory devices can include the selected portions arranged in alternating positions between an upper portion of a plane in which the BLs are structured and a lower portion of the plane. The selected portions can have a width corresponding to width and separation of a packet of BLs structured in formation of the memory device. The packet of BLs can have eight BLs arranged in parallel. The array of pillars can be implemented such that the organization of the array of pillars in blocks does not include dummy blocks that are not useable to store data.

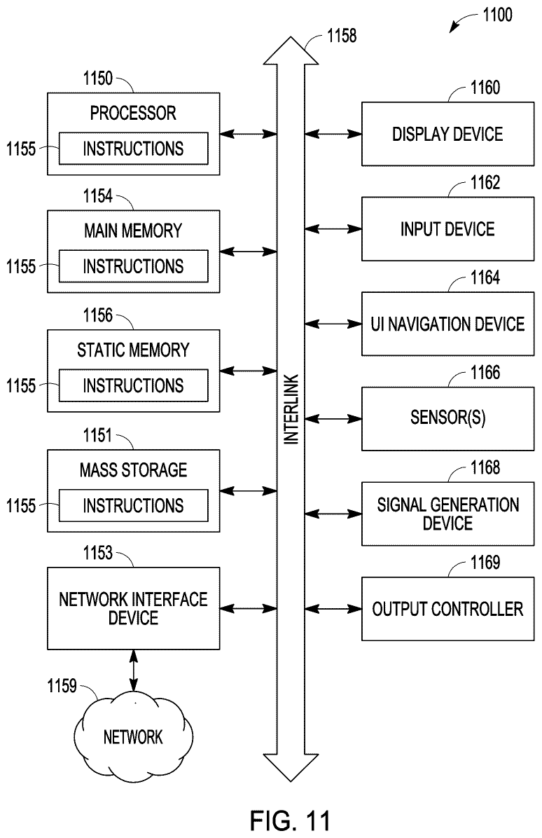

FIG. 11 illustrates a block diagram of an example machine 1100 having one or more memory devices structured with an array of blocks of pillars of memory cells, including separation regions between blocks defined by spacing of a single row of pillars, except for two dedicated separation regions providing spacing defined by three rows of pillars. The machine 1100, having one or more such memory devices, may operate as a standalone machine or may be connected, for example networked, to other machines.

In a networked deployment, the machine 1100 may operate in the capacity of a server machine, a client machine, or both in server-client network environments. In an example, the machine 1100 may act as a peer machine in peer-to-peer (P2P) (or other distributed) network environment. The machine 1100 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The example machine 1100 can be arranged to operate with one or more memory devices structured with an array of blocks of pillars of memory cells, including separation regions between blocks defined by spacing of a single row of pillars, except for two dedicated separation regions providing spacing defined by three rows of pillars, as taught herein.

The machine (e.g., computer system) 1100 may include a hardware processor 1150 (e.g., a CPU, a GPU, a hardware processor core, or any combination thereof), a main memory 1154, and a static memory 1156, some or all of which may communicate with each other via an interlink (e.g., bus) 1158. The machine 1100 may further include a display device 1160, an alphanumeric input device 1162 (e.g., a keyboard), and a user interface (UI) navigation device 1164 (e.g., a mouse). In an example, the display device 1160, input device 1162, and UI navigation device 1164 may be a touch screen display. The machine 1100 may additionally include a mass storage device (e.g., drive unit) 1151, a signal generation device 1168 (e.g., a speaker), a network interface device 1153, and one or more sensors 1166, such as a global positioning system (GPS) sensor, compass, accelerometer, or other sensor. The machine 1100 may include an output controller 1169, such as a serial (e.g., USB, parallel, or other wired or wireless (e.g., infrared (IR), near field communication (NFC), etc.) connection to communicate or control one or more peripheral devices (e.g., a printer, card reader, etc.).

The machine 1100 may include machine-readable media on which is stored one or more sets of data structures or instructions 1155 (e.g., software) embodying or utilized by the machine 1100 to perform any one or more of the techniques or functions for which the machine 1100 is designed. The machine-readable media can include main memory 1154, static memory 1156, or mass storage device 1151. The instructions 1155 may reside, completely or at least partially, within main memory 1154, within static memory 1156, within the mass storage device 1151, or within the hardware processor 1150 during execution thereof by the machine 1100.

While each of the machine-readable media is illustrated as a single medium, the term “machine-readable medium” may include a single medium or multiple media (e.g., a centralized or distributed database, or associated caches and servers) configured to store the one or more instructions 1155. The term “machine-readable medium” may include any medium that is capable of storing, encoding, or holding instructions for execution by the machine 1100 and that cause the machine 1100 to perform any one or more of the techniques to which the machine 1100 is designed, or that is capable of storing, encoding, or holding data structures used by or associated with such instructions. Non-limiting machine-readable medium examples may include solid-state memories, optical and magnetic media, or other tangible structures. Examples of machine-readable media can include non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

The instructions 1155 (e.g., software, programs, an operating system (OS), etc.) or other data, stored on the mass storage device 1151, can be accessed by the main memory 1154 for use by the processor 1150. The main memory 1154 (e.g., DRAM) is typically fast, but volatile, and thus a different type of storage than the mass storage device 1151 (e.g., an SSD), which is suitable for long-term storage, including while in an “off” condition. The instructions 1155 or data in use by a user or the machine 1100 are typically loaded in the main memory 1154 for use by the processor 1150. When the main memory 1154 is full, virtual space from the mass storage device 1151 can be allocated to supplement the main memory 1154; however, because the mass storage device 1151 is typically slower than the main memory 1154, and write speeds are typically at least twice as slow as read speeds, use of virtual memory can greatly reduce user experience due to storage device latency (in contrast to the main memory 1154, e.g., DRAM). Further, use of the mass storage device 1151 for virtual memory can greatly reduce the usable lifespan of the mass storage device 1151.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA-based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

The instructions 1155 may further be transmitted or received over a communications network 1159 using a transmission medium via the network interface device 1153 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1153 may include one or more physical jacks (e.g., Ethernet, coaxial, or phone jacks) or one or more antennas to connect to the communications network 1159. In an example, the network interface device 1153 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by the machine 1100, and includes instrumentalities to propagate digital or analog communications signals to facilitate communication of such instructions, which instructions may be implemented by software.

The following examples are example embodiments of devices and methods, in accordance with the teachings herein.

An example memory device 1 can comprise an array of pillars of memory cells, the memory cells stacked in a vertical direction within the pillars, the array of pillars organized in blocks; separation regions between blocks defined by spacing of a single row of pillars, except for two dedicated separation regions providing spacing defined by three rows of pillars; and BLs in a parallel arrangement and positioned above the pillars, each BL coupled to memory cells of selected pillars, the BLs extending over the separation regions and the two dedicated separation regions except over selected portions of the two dedicated separation regions at which the BLs are arranged in two separate sets.

An example memory device 2 can include features of example memory device 1 and can include the selected portions being arranged in alternating positions between an upper portion of a plane in which the BLs are structured and a lower portion of the plane.

An example memory device 3 can include features of memory device 2and any of the preceding example memory devices and can include the selected portions having a width corresponding to width and separation of a packet of BLs structured in formation of the memory device.

An example memory device 4 can include features of example memory device 3 and any of the preceding example memory devices 1 to 2 and can include the packet of BLs having eight BLs arranged in parallel.

An example memory device 5 can include features of any of the preceding example memory devices and can include organization of the array of pillars not including dummy blocks that are not useable to store data.

In an example memory device 6, any of the memory devices of example memory devices 1 to 5 may include memory devices incorporated into an electronic apparatus further comprising a host processor or memory controller and a communication bus extending between the host processor/memory controller and the memory device.

In an example memory device 7, any of the memory devices of example memory devices 1 to 6 may be modified to include any structure presented in another of example memory device 1 to 6.

In an example memory device 8, any apparatus associated with the memory devices of example memory devices 1 to 7 may further include a machine-readable storage device configured to store instructions as a physical state, wherein the instructions may be used to perform one or more operations of the apparatus.

In an example memory device 9, any of the memory devices of example memory devices 1 to 8 may be operated in accordance with any of the below example methods 1 to 11 and methods 12 to 16.

An example method 1 can comprise forming an array of pillars of memory cells, with the memory cells stacked in a vertical direction within the pillars and with the array of pillars organized in blocks; forming separation regions between blocks defined by spacing of a single row of pillars, except for two dedicated separation regions providing spacing defined by three rows of pillars; and forming BLs in a parallel arrangement and positioned above the pillars, each BL coupled to memory cells of selected pillars, the BLs extending over the separation regions and the two dedicated separation regions except over selected portions of the two dedicated separation regions at which the BLs are cut forming two separate sets of BLs along a direction in a plane.

An example method 2 can include features of example method 1 and can include forming the selected portions to include arranging the selected portions in alternating positions between an upper portion of a plane in which the BLs are structured and a lower portion of the plane.

An example method 3 can include features of any of the preceding example methods and can include forming the selected portions to include forming the selected portions having a width corresponding to width and separation of a packet of BLs structured in forming the BLs.

An example method 4 can include features of any of the preceding example methods and can include forming the BLs to include forming the BLs in packets of BLs having eight BLs arranged in parallel.

An example method 5 can include features of any of the preceding example methods and can include forming the array of pillars to include organizing the array of pillars without forming dummy blocks that are not useable to store data.

An example method 6 can include features of any of the preceding example methods and can include forming memory cells within pillars of active blocks of the array before forming and cutting BLs in the selected portions of the two dedicated separation regions.

An example method 7 can include features of any of the preceding example methods and can include merging the three rows of pillars in each of the two separation regions and forming an electrical isolation between blocks directly adjacent the two separation regions.

In an example method 8, any of the example methods 1 to 7 may be performed in forming an electronic apparatus further comprising a host processor and a communication bus extending between the host processor and a memory system.

In an example method 9, any of the example methods 1 to 8 may be modified to include operations set forth in any other of example methods 1 to 8.

In an example method 10, any of the example methods 1 to 9 may be implemented at least in part through use of instructions stored as a physical state in one or more machine-readable storage devices.

An example method 11 can include features of any of the preceding example methods 1 to 10 and can include performing functions associated with any features of example memory devices 1 to 9.

An example method 12 can comprise forming an array of pillars for memory cells of a memory device, the array of pillars organized in blocks with separation regions between blocks defined by a single row of pillars, except for two dedicated separation regions having three rows of pillars, the two dedicated separation regions dedicated to BL cuts; forming a first packet of connected BLs in a first direction in a plane extending across and on a first set of the pillars and at least partially on a first separation region of the two dedicated separation regions; forming a second packet of connected BLs in the first direction in the plane extending across and on a second set of the pillars and at least partially on the first separation region, an end of the second packet separated from an end of the first packet on the first separation region in the first direction; forming a mask on the first packet and the second packet on the first separation region; and cutting the first packet and the second packet at two opposite edges of the mask across the connected BLs.

An example method 13 can include features of example method 12 and can include forming a third packet of connected BLs in a second direction in the plane extending across and on a third set of the pillars and at least partially on a second separation region of the two dedicated separation regions; forming a fourth packet of connected BLs with the fourth packet in the second direction in the plane extending across and on a fourth set of the pillars and at least partially on the second separation region, an end of the third packet separated from an end of the fourth packet on the second separation region in the second direction; forming a second mask on the third packet and the fourth packet on the second separation region; and cutting the third packet and the fourth packet at two opposite edges of the second mask across the connected BLs.

An example method 14 can include features of example method 13 and any of the preceding example methods 12 to 13 and can include the first direction and the second direction being parallel to each other and the third packet and the fourth packet being adjacent the first packet and the second packet without an intervening packet between combination of the third packet and the fourth packet and combination of the first packet and the second packet.

An example method 15 can include features of any of the preceding example methods and can include forming each packet of the first packet and the second packet to include forming eight BLs in parallel to each other in the first direction and forming four BL connectors connecting the eight BLs on a pair-wise basis in a direction perpendicular to the first direction.

An example method 16 can include features of example method 15 and any of the preceding example methods and can include forming the mask to include forming the mask on the four BL connectors.

An example method 17 can include features of any of the preceding example methods and can include forming the three rows in each of the two dedicated separation regions with the two dedicated separation regions separated from each other in the first direction by one or more active blocks of memory cells.

An example method 18 can include features of any of the preceding example methods and can include forming memory cells within pillars of active blocks of the array before forming and cutting the first packet and the second packet.

An example method 19 can include features of any of the preceding example methods and can include merging the three rows of pillars in each of the two separation regions and forming an electrical separation between blocks directly adjacent the two separation regions.

In an example method 20, any of the example methods 12 to 19 may be performed in forming an electronic apparatus further comprising a host processor and a communication bus extending between the host processor and a memory system.

In an example method 21, any of the example methods 12 to 20 may be modified to include operations set forth in any other of example methods 12 to 20.

In an example method 22, any of the example methods 12 to 21 may be implemented at least in part through use of instructions stored as a physical state in one or more machine-readable storage devices.

An example method 23 can include features of any of the preceding example methods 12 to 22 and can include performing functions associated with any features of example memory devices 1 to 9.

An example machine-readable storage device storing instructions, that when executed by one or more processors, cause a machine to perform operations, can comprise instructions to perform functions associated with any features of example memory devices 1 to 9 or perform form methods associated with any features of example methods 1 to 11 or example methods 12 to 23.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of pillars of memory cells, the memory cells stacked in a vertical direction within the pillars, the array of pillars organized in blocks;
separation regions between blocks defined by spacing of a single row of pillars, except for two dedicated separation regions providing spacing defined by three rows of pillars; and
data lines in a parallel arrangement and positioned above the pillars, each data line coupled to memory cells of selected pillars, the data lines extending over the separation regions and the two dedicated separation regions except over selected portions of the two dedicated separation regions at which the data lines are arranged in two separate sets.

2. The memory device of claim 1, wherein the selected portions are arranged in alternating positions between an upper portion of a plane in which the data lines are structured and a lower portion of the plane.

3. The memory device of claim 2, wherein the selected portions have a width corresponding to width and separation of a packet of data lines structured in formation of the memory device.

4. The memory device of claim 3, where the packet of data lines has eight data lines arranged in parallel.

5. The memory device of claim 1, wherein organization of the array of pillars does not include dummy blocks that are not useable to store data.

6. A method comprising:
forming an array of pillars of memory cells, with the memory cells stacked in a vertical direction within the pillars and with the array of pillars organized in blocks;
forming separation regions between blocks defined by spacing of a single row of pillars, except for two dedicated separation regions providing spacing defined by three rows of pillars; and
forming data lines in a parallel arrangement and positioned above the pillars, each data line coupled to memory cells of selected pillars, the data lines extending over the separation regions and the two dedicated separation regions except over selected portions of the two dedicated separation regions at which the data lines are cut, forming two separate sets of data lines along a direction in a plane.

7. The method of claim 6, wherein forming the selected portions includes arranging the selected portions in alternating positions between an upper portion of a plane in which the data lines are structured and a lower portion of the plane.

8. The method of claim 6, wherein forming the selected portions include forming the selected portions having a width corresponding to width and separation of a packet of data lines structured in forming the data lines.

9. The method of claim 6, wherein forming the data lines includes forming the data lines in packets of data lines having eight data lines arranged in parallel.

10. The method of claim 6, wherein forming the array of pillars includes organizing the array of pillars without forming dummy blocks that are not useable to store data.

11. The method of claim 6, wherein includes forming memory cells within pillars of active blocks of the array before forming and cutting data lines in the selected portions of the two dedicated separation regions.

12. The method of claim 6, wherein the method includes merging the three rows of pillars in each of the two separation regions and forming an electrical isolation between blocks directly adjacent the two separation regions.

13. A method comprising:
forming an array of pillars for memory cells of a memory device, the array of pillars organized in blocks with separation regions between blocks defined by a single row of pillars, except for two dedicated separation regions having three rows of pillars, the two dedicated separation regions dedicated to data line cuts;
forming a first packet of connected data lines in a first direction in a plane extending across and on a first set of the pillars and at least partially on a first separation region of the two dedicated separation regions;
forming a second packet of connected data lines in the first direction in the plane extending across and on a second set of the pillars and at least partially on the first separation region, an end of the second packet separated from an end of the first packet on the first separation region in the first direction;
forming a mask on the first packet and the second packet on the first separation region; and
cutting the first packet and the second packet at two opposite edges of the mask across the connected data lines.

14. The method of claim 13, wherein the method includes:
forming a third packet of connected data lines in a second direction in the plane extending across and on a third set of the pillars and at least partially on a second separation region of the two dedicated separation regions;
forming a fourth packet of connected data lines with the fourth packet in the second direction in the plane extending across and on a fourth set of the pillars and at least partially on the second separation region, an end of the third packet separated from an end of the fourth packet on the second separation region in the second direction;
forming a second mask on the third packet and the fourth packet on the second separation region; and
cutting the third packet and the fourth packet at two opposite edges of the second mask across the connected data lines.

15. The method of claim 14, wherein the first direction and the second direction are parallel to each other and the third packet and the fourth packet are adjacent the first packet and the second packet without an intervening packet between combination of the third packet and the fourth packet and combination of the first packet and the second packet.

16. The method of claim 13, wherein forming each packet of the first packet and the second packet includes forming eight data lines in parallel to each other in the first direction and forming four data line connectors connecting the eight data lines on a pair-wise basis in a direction perpendicular to the first direction.

17. The method of claim 16, wherein forming the mask includes forming the mask on the four data line connectors.

18. The method of claim 13, wherein the method includes forming the three rows in each of the two dedicated separation regions with the two dedicated separation regions separated from each other in the first direction by one or more active blocks of memory cells.

19. The method of claim 13, wherein the method includes forming memory cells within pillars of active blocks of the array before forming and cutting the first packet and the second packet.

20. The method of claim 13, wherein the method includes merging the three rows of pillars in each of the two separation regions and forming an electrical separation between blocks directly adjacent the two separation regions.
